(19) United States
(12) Patent Application Publication
(10) Pub. No.: US 2025/0231124 A1
(43) Pub. Date: Jul. 17, 2025

(54) INSPECTION DEVICE, INSPECTION ELEMENT, AND INSPECTION METHOD

(71) Applicant: Hitachi High-Tech Corporation, Minato-ku, Tokyo (JP)

(72) Inventors: Yoshihiro ANAN, Tokyo (JP); Takeyoshi OHASHI, Tokyo (JP); Shin IMAMURA, Tokyo (JP)

(21) Appl. No.: 18/854,300

(22) PCT Filed: Jun. 8, 2022
(86) PCT No.: PCT/JP2022/023154

§ 371 Date: Oct. 4, 2024

(51) Int. Cl. G01N 23/18; G01N 23/046

(52) U.S. Cl. CPC G01N 23/18; G01N 23/046; G01N 2223/045; G01N 2223/079; G01N 2223/102; G01N 2223/505; G01N 2223/507

(57) ABSTRACT

Performance of an inspection device is improved. For example, in an inspection device 100 including an electron detection element 30 and an X-ray detection element 40, the electron detection element 30 is provided between an electron source 10 and a sample stage 14 on which a sample 20 can be provided, and the X-ray detection element 40 is provided between the electron detection element 30 and the electron source 10, and the electron detection element 30 and the X-ray detection element 40 are provided to overlap each other in a plan view.

### TECHNICAL FIELD

The present invention relates to an inspection device, an inspection element, and an inspection technique, for example, relates to a technique that is effective when applied to an inspection device, an inspection element, and an inspection method used in the inspection of a semiconductor device.

### BACKGROUND ART

Japanese Patent No. 6416199 (PTL 1) discloses a technique related to a detector and an electron detector capable of detecting X-rays and electrons.

### CITATION LIST

### Patent Literature

PTL 1: JP6416199

### SUMMARY OF INVENTION

### Technical Problem

There is a step of inspecting an etching defect of a deep hole (for example, a contact hole or a via hole) formed in a semiconductor device in an inspection step of the semiconductor device. In the inspection process, for example, an inspection device (scanning electron microscope) that inspects an etching defect of a deep hole by irradiating the deep hole with primary electrons generated by an electron source and detecting secondary electrons and back scattered electrons emitted from the deep hole. In the present specification, when there is no need to distinguish between secondary electrons and back scattered electrons, they are simply referred to as electrons.

In this regard, in recent years, an aspect ratio of the deep hole is increasing with increasing integration and miniaturization of the semiconductor device. When the aspect ratio of the deep hole is increased as described above, the probability of the electrons generated from a bottom portion of the deep hole being absorbed by a side wall of the deep hole is increased. As a result, it is difficult to acquire information of the bottom portion of the deep hole. This means that it is difficult to detect the etching defect of the deep hole, and improvement is required.

Therefore, attempts have been made to obtain information about the bottom portion of the deep hole by using X-rays, which have high transmittance. Specifically, it is considered that an electron detection element for detecting electrons and an X-ray detection element for detecting X-rays are provided in the inspection device. However, in the studied technique, a configuration in which the electron detection element and the X-ray detection element do not overlap each other is considered.

In the case of the inspection device having such a configuration, a solid angle at which electrons are incident from the deep hole to the electron detection element and a solid angle at which the X-rays are incident on the X-ray detection element from the deep hole are small. This means that the electron detection element cannot detect electrons with high efficiency, and the X-ray detection element cannot detect the X-rays with high efficiency.

Therefore, in a technique of providing an electron detection element for detecting electrons and an X-ray detection element for detecting X-rays in an inspection device, development of an inspection device capable of accurately inspecting an etching defect of a deep hole having a high aspect ratio is desired. That is, in an inspection device including an electron detection element and an X-ray detection element, improvements in enabling inspection of an etching defect of a deep hole having a high aspect ratio with high accuracy are desired.

### Solution to Problem

In one embodiment, an inspection device includes: an electron source configured to generate primary electrons to be incident on a sample; an electron detection element located between a sample stage on which the sample is allowed to be provided and the electron source; and an X-ray detection element located between the electron detection element and the electron source. Here, the electron detection element includes a first scintillator that detects electrons emitted from the sample, and the X-ray detection element is configured to detect an X-ray emitted from the sample, that is, the X-ray transmitted through the electron detection element.

In one embodiment, an inspection element is an inspection element that is allowed to be incorporated into an inspection device that causes primary electrons generated by an electron source to be incident on a sample provided on a sample stage and detects an electron and an X-ray emitted from the sample. Here, the inspection element includes: an electron detection element that is allowed to be provided between the sample stage and the electron source; and an X-ray detection element that is allowed to be provided between the electron detection element and the electron source. Further, the electron detection element includes a scintillator that detects the electron emitted from the sample, and the X-ray detection element is configured to detect the X-ray emitted from the sample, that is, the X-ray transmitted through the electron detection element.

In one embodiment, an inspection method includes: a step of causing primary electrons to be generated by an electron source to be incident on a sample; and a step of detecting an electron emitted from the sample by an electron detection element which is located between a sample stage on which the sample is provided and the electron source and which includes a scintillator, and detecting the X-ray emitted from the sample, that is, the X-ray transmitted through the electron detection element by an X-ray detection element located between the electron detection element and the electron source.

### Advantageous Effects of Invention

According to one embodiment, performance of the inspection device can be improved.

### BRIEF DESCRIPTION OF DRAWINGS

FIG. 1 is a diagram showing a schematic configuration of an inspection device.

FIG. 2A is a diagram schematically showing a planar shape of an electron detection element when viewed in a plane perpendicular to an incident direction of a primary electron, and FIG. 2B is a diagram schematically showing a planar shape of an X-ray detection element when viewed in a plane perpendicular to the incident direction of the primary electron.

FIG. 3A is a graph showing a calculation result of “SNR” calculated based on a back scattered electron intensity from a bottom portion of a deep hole, and FIG. 3B is a graph showing a calculation result of the “SNR” calculated based on an X-ray intensity from the bottom portion of the deep hole.

FIG. 4 is a diagram showing a configuration of a modification.

FIG. 5 is a diagram showing a functional block configuration of a control unit.

FIG. 6 is a flowchart showing an operation of the inspection device.

FIG. 7 is a schematic view showing a deep hole sample.

(a) of FIG. 8 is a diagram schematically showing an electronic image generated based on an output from the electron detection element, (b) of FIG. 8 is a diagram schematically showing an X-ray image generated based on an output from the X-ray detection element, and (c) of FIG. 8 is a diagram showing a composite image obtained by combining a feature of the electronic image and a feature of the X-ray image.

### DESCRIPTION OF EMBODIMENTS

In the drawings for illustrating the embodiment, the same members are denoted by the same reference signs in principle, and repeated description thereof is omitted. To facilitate understanding of the drawings, hatching may be applied to a plane view.

### Configuration of Inspection Device

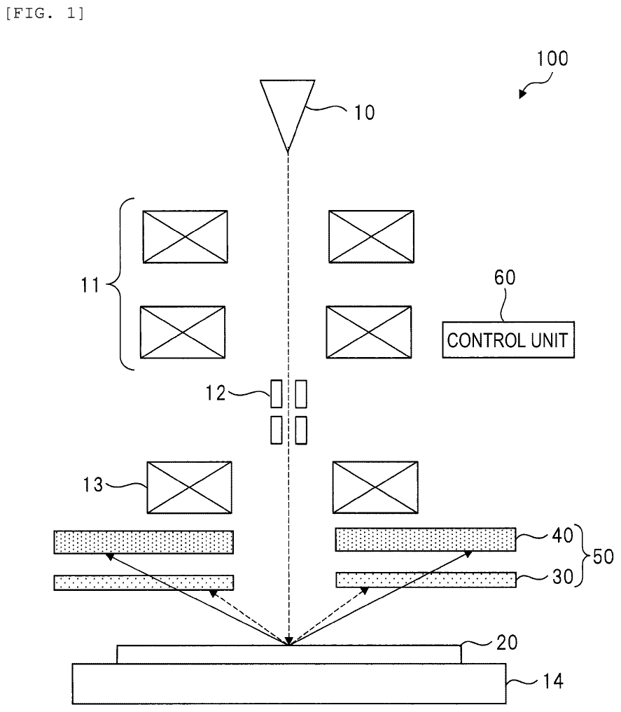

FIG. 1 is a diagram showing a schematic configuration of an inspection device 100.

In FIG. 1, the inspection device 100 includes an electron source 10, a converging lens 11, a deflector 12, an objective lens 13, a sample stage 14, an inspection element 50, and a control unit 60.

The electron source 10 is implemented to generate a plurality of primary electrons. The converging lens 11 has a function of converging a primary electron beam formed of the plurality of primary electrons generated by the electron source 10. The objective lens 13 has a function of focusing the primary electron beam on a sample 20 placed on the sample stage 14. The deflector 12 is implemented to be able to change a traveling direction of the primary electron beam. The deflector 12 enables an irradiation position of the primary electron beam on the sample 20 to be scanned along an inspection range.

The inspection element 50 is implemented to be capable of detecting electrons and X-rays emitted by making the primary electrons incident on the sample 20, and includes an electron detection element 30 that detects electrons and an X-ray detection element 40 that detects X-rays.

As shown in FIG. 1, the electron detection element 30 is provided between the sample stage 14 on which the sample 20 is provided and the electron source 10. More specifically, the electron detection element 30 is provided between the sample stage 14 and the objective lens 13. Meanwhile, the X-ray detection element 40 is provided between the electron detection element 30 and the electron source 10. More specifically, the X-ray detection element 40 is provided between the electron detection element 30 and the objective lens 13.

Further, the electron detection element 30 includes, for example, a scintillator that detects electrons emitted from the sample 20, and a photomultiplier tube that amplifies light generated in the scintillator. The X-ray detection element 40 is implemented to detect X-rays emitted from the sample 20 and transmitted through the electron detection element 30, and is implemented, for example, from a semiconductor detector such as a silicon drift detector, or a combination of a scintillator and a photomultiplier tube. In the present embodiment, it is assumed that the electron detection element 30 is formed of the combination of the scintillator and the photomultiplier tube, and the X-ray detection element 40 is also formed of the combination of the scintillator and the photomultiplier tube.

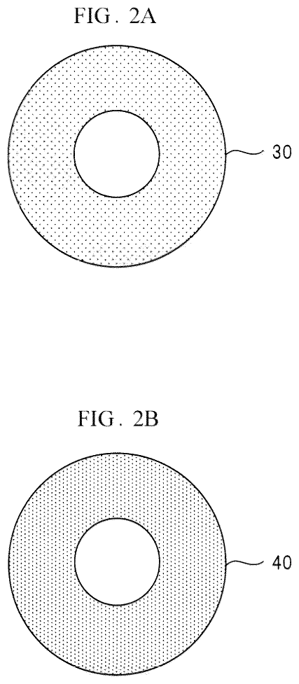

FIG. 2A is a diagram schematically showing a planar shape of the electron detection element 30 when viewed in a plane perpendicular to an incident direction of a primary electron, and FIG. 2 is a diagram schematically showing a planar shape of the X-ray detection element 40 when viewed in a plane perpendicular to the incident direction of the primary electron.

As shown in FIG. 2A, the planar shape of the electron detection element 30 has a concentric circular shape having a hollow portion through which the primary electrons pass through a central portion thereof, and the electron detection element 30 is formed of a so-called “annular element”. Similarly, as shown in FIG. 2B, the planar shape of the X-ray detection element 40 has a concentric circular shape having a hollow portion through which the primary electrons pass through the central portion, and the X-ray detection element 40 is also formed of the so-called “annular element”.

The inspection element 50 formed in this manner can be manufactured and sold as an integral part of the inspection device 100 that emits the primary electrons (primary electron beam) generated by the electron source 10 onto the sample 20 provided on the sample stage 14 and detects the electrons and the X-rays emitted from the sample 20, but it can also be manufactured and sold as the inspection element 50 alone.

Next, the control unit 60 is implemented to control the operation of the inspection device 100. Specifically, the control unit 60 is implemented to perform control for converging the primary electron beam by the converging lens 11 and the objective lens 13, control for scanning of the primary electron beam by the deflector 12, control for performing signal processing for an output signal from the inspection element 50, control for image generation processing based on the output signal from the inspection element 50 and image display processing, and the like.

The inspection device 100 according to the present embodiment is implemented as described above.

### Operation of Inspection Device

Next, the operation of the inspection device 100 will be described with reference to FIG. 1.

First, the sample 20 is placed on the sample stage 14. Then, the plurality of primary electrons are generated in the electron source 10, and the primary electron beam formed of the plurality of primary electrons are emitted from the electron source 10. The primary electron beam emitted from the electron source 10 is converged by the converging lens 11 and then passes through the deflector 12, so that the traveling direction is adjusted. Thereafter, the primary electron beam whose traveling direction is adjusted by the deflector 12 is emitted onto a first region of the sample 20 by the objective lens 13.

In the first region of the sample 20, when the primary electron beam is emitted, for example, the primary electrons collide with electrons bound to atoms (molecules) constituting the sample 20, and as a result, the electrons bound to the atoms constituting the sample 20 are scattered and ejected from the atoms. The ejected electrons are secondary electrons. The primary electrons may be scattered backward from the atoms constituting the sample 20, and the primary electrons scattered backward and emitted from the sample 20 are back scattered electrons.

When the sample 20 is irradiated with the primary electron beam, the secondary electrons and the back scattered electrons are emitted from the sample 20. Further, X-rays are radiated from the scattered secondary electrons and back scattered electrons, and the like by braking radiation. Therefore, when the sample 20 is irradiated with the primary electron beam, not only the secondary electrons and the back scattered electrons (collectively referred to as “electrons”) are emitted from the sample 20, but also the X-rays are emitted.

Next, the “electrons” emitted from the sample 20 are incident on the electron detection element 30 provided between the objective lens 13 and the sample stage 14. The “electrons” incident on the electron detection element 30 are converted into light by the scintillator that is a component of the electron detection element 30. The light converted by the scintillator is photoelectrically converted and amplified by the photomultiplier tube, which is a component of the electron detection element 30, and is output from the electron detection element 30 as the output signal.

Meanwhile, the X-rays emitted from the sample 20 pass through the electron detection element 30 and then incident on the X-ray detection element 40 provided between the objective lens 13 and the electron detection element 30. The X-rays incident on the X-ray detection element 40 are converted into light by the scintillator that is the component of the X-ray detection element 40. The light converted by the scintillator is photoelectrically converted and amplified by the photomultiplier tube, which is the component of the X-ray detection element 40, and is output from the X-ray detection element 40 as the output signal.

Next, the output signal output from the electron detection element 30 is converted into, for example, an image signal, and then an electronic image is acquired based on the image signal, and the electronic image is displayed. Meanwhile, the output signal output from the X-ray detection element 40 is converted into, for example, an image signal, and then an X-ray image is acquired based on the image signal, and the X-ray image is displayed.

Thereafter, the traveling direction of the primary electron beam is changed by the deflector 12, and the primary electron beam is scanned from the first region to a second region of the sample 20. Further, in the second region of the sample 20, an operation same as the operation in the first region is repeated.

In this way, the inspection device 100 operates.

### Features of Embodiment

Next, features in the present embodiment will be described.

A first feature in the present embodiment is that, for example, as shown in FIG. 1, in the inspection device 100 including the electron detection element 30 and the X-ray detection element 40, the electron detection element 30 is provided between the electron source 10 and the sample stage 14 on which the sample 20 can be provided, and the X-ray detection element 40 is provided between the electron detection element 30 and the electron source 10, and the electron detection element 30 and the X-ray detection element 40 are provided to overlap each other in a plan view.

Accordingly, according to the first feature, the “electrons” emitted from the sample 20 are absorbed by the electron detection element 30 provided in front of the X-ray detection element 40. As a result, the incidence of the “electrons” on the X-ray detection element 40 is limited, and thus detection accuracy of the X-rays in the X-ray detection element 40 can be improved. That is, since the output signal is generated even when the “electrons” are incident on the X-ray detection element 40, the output signal caused by the “electrons” becomes noise. Therefore, in order to improve the detection accuracy of the X-rays, it is desirable to prevent the “electrons” from being incident on the X-ray detection element 40 as much as possible.

In this regard, according to the first feature, since the electron detection element 30 is provided on a side close to the sample 20, the electron detection element 30 functions as a shielding member that limits the incidence of the “electrons” on the X-ray detection element 40. Therefore, according to the first feature, it is possible to improve the detection accuracy of the X-rays by the X-ray detection element 40.

Here, in order to cause the electron detection element 30 to function as the shielding member, it is desirable that a film thickness of the electron detection element 30 has a sufficient film thickness for absorbing the “electrons” and has a sufficient density to absorb the “electrons”. In this case, since the number of “electrons” absorbed by the electron detection element 30 increases, the detection efficiency of the “electrons” in the electron detection element 30 can be improved according to the first feature.

Since the X-rays emitted from the sample 20 have high transmittance, the X-rays pass through the electron detection element 30 in front and incident on the X-ray detection element 40. Therefore, even if the configuration of the first feature is employed, there is no problem in detection of X-rays.

From the above, according to the first feature, it is possible to cause the electron detection element 30 to function as the shielding member that limits the incidence of the “electrons” to the X-ray detection element 40 without sacrificing the incidence of the X-rays to the X-ray detection element 40. As a result, the inspection device 100 according to the present embodiment can improve the detection accuracy of the X-rays.

A second feature in the present embodiment is that, for example, as shown in FIG. 2A and FIG. 2B, the electron detection element 30 is the “annular element”, and the X-ray detection element 40 is also the “annular element”. In other words, the second feature is that the planar shape of the electron detection element 30 has a concentric circular shape having a hollow portion through which the primary electron passes in the central portion, and similarly, the planar shape of the X-ray detection element 40 is also a concentric circular shape having a hollow portion through which the primary electron passes in the central portion.

Accordingly, according to the second feature, it is possible to increase the solid angle at which the “electrons” are incident on the electron detection element 30 from the sample 20 and the solid angle at which the X-rays are incident on the X-ray detection element 40 from the sample 20. This means that the “electrons” can be converted into light with high efficiency by the electron detection element 30, and the X-rays can be converted into light with high efficiency by the X-ray detection element 40. According to the second feature, the detection efficiency of the “electrons” and the detection efficiency of the X-rays in the inspection device 100 can be improved.

As described above, according to the inspection device 100 in the present embodiment, performance of the inspection device 100 can be improved by a synergistic effect of the first feature and the second feature described above.

### Verification of Effects

According to the above-described features, a verification result that the detection accuracy of the X-rays in the inspection device 100 can be improved will be described. The verification is performed by calculating a back scattered electron intensity (BSE intensity) and an X-ray intensity for a deep hole sample. Specifically, the verification is performed by calculating a signal noise ratio: contrast (SNR) based on a signal intensity from the bottom portion of the deep hole.

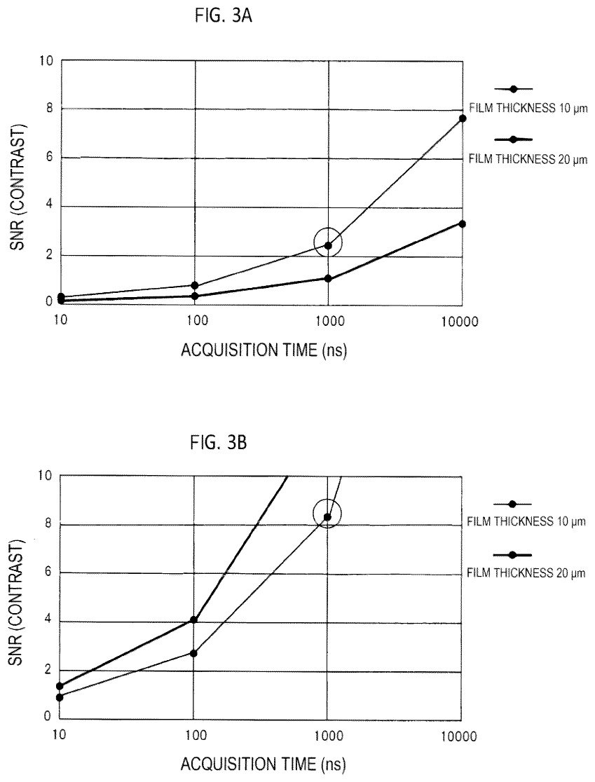

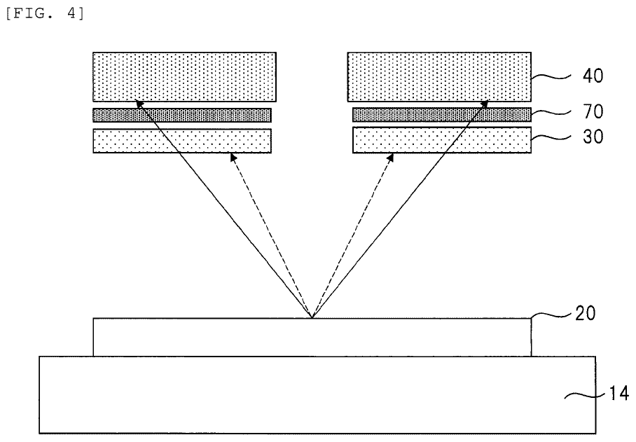

FIG. 3A is a graph showing the calculation result of the “SNR” calculated based on the back scattered electron intensity from the bottom portion of the deep hole, and FIG. 3B is a graph showing the calculation result of the “SNR” calculated based on the X-ray intensity from the bottom portion of the deep hole.

As shown in FIG. 3A and FIG. 3B, the “SNR” based on the back scattered electron intensity is about 2 (points surrounded by a circle), and the “SNR” based on the X-ray intensity is about 8 (points surrounded by a circle). This means that the “SNR” based on the X-ray intensity has a contrast about four times higher than the “SNR” based on the back scattered electron intensity. That is, according to the verification result described above, it is understood that sensitivity of the deep hole with respect to information from the bottom portion is better when the detection of the X-rays by the X-ray detection element 40 is used rather than using the detection of the back scattered electrons by the electron detection element 30. Based on such a verification result, it is understood that the inspection device 100 according to the present embodiment can accurately detect information from the bottom portion of the deep hole by using the output from the X-ray detection element 40. That is, by using the inspection device 100 according to the present embodiment, for example, an etching defect of a deep hole having a high aspect ratio can be inspected with high accuracy.

### Modification

Next, a modification will be described.

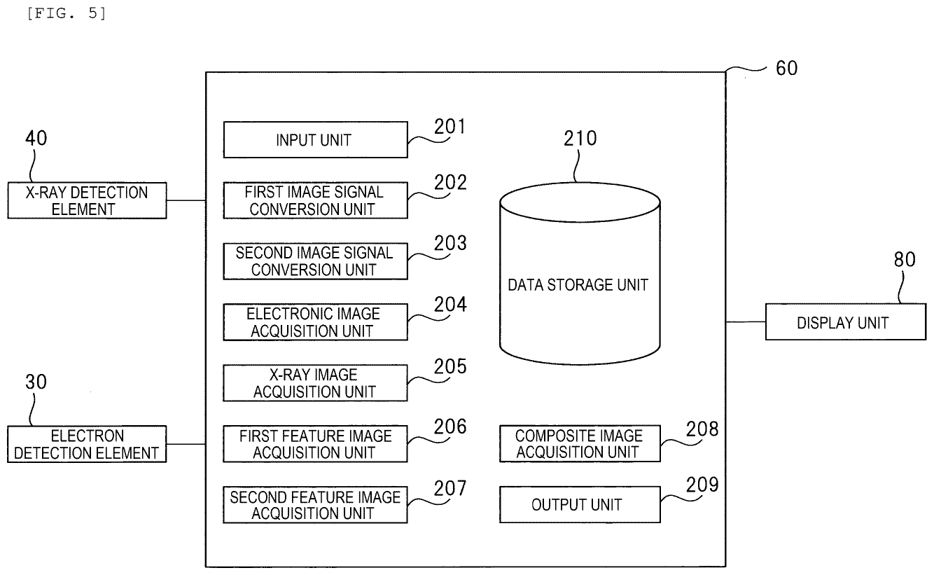

FIG. 4 is a diagram showing a configuration of the modification. In FIG. 4, in the present modification, a crosstalk limit unit 70 is provided between the electron detection element 30 and the X-ray detection element 40 to limit crosstalk between the light generated from the scintillator included in the electron detection element 30 and the light generated from the scintillator included in the X-ray detection element 40.

Accordingly, according to the present modification, it is possible to prevent the light generated by the electron detection element 30 from intruding the X-ray detection element 40 and being detected by the photomultiplier tube of the X-ray detection element 40, and limiting the light generated by the X-ray detection element 40 from intruding the electron detection element 30 and being detected by the photomultiplier tube of the electron detection element 30. That is, according to the present modification, superimposition of noise signals can be reduced in each of the electron detection element 30 and the X-ray detection element 40. As a result, according to the present modification, the detection accuracy of the “electrons” by the electron detection element 30 and the detection accuracy of the X-rays by the X-ray detection element 40 can be improved.

For example, the crosstalk limit unit 70 may include a shielding film that shields the light generated from the scintillator included in the electron detection element 30 and the light generated from the scintillator included in the X-ray detection element 40.

However, the crosstalk limit unit 70 may include not only the above-described shielding film, but also, for example, a film having a refractive index different from a refractive index of a material constituting the electron detection element 30 and a refractive index of a material constituting the X-ray detection element 40, or a space region having a refractive index different from the refractive index of the material constituting the electron detection element 30 and the refractive index of the material constituting the X-ray detection element 40.

Specifically, the crosstalk limit unit 70 may include a film having a refractive index smaller than the refractive index of the material constituting the electron detection element 30 and the refractive index of the material constituting the X-ray detection element 40, or a space region having a refractive index smaller than the refractive index of the material constituting the electron detection element 30 and the refractive index of the material constituting the X-ray detection element 40.

In this case, the light generated from the scintillator included in the electron detection element 30 is totally reflected by a refractive index difference at a boundary between the electron detection element 30 and the crosstalk limit unit 70. In other words, the light generated from the scintillator included in the electron detection element 30 is confined inside the electron detection element 30. Similarly, the light generated from the scintillator included in the X-ray detection element 40 is totally reflected by a refractive index difference at a boundary between the X-ray detection element 40 and the crosstalk limit unit 70. In other words, the light generated from the scintillator included in the X-ray detection element 40 is confined inside the X-ray detection element 40. Accordingly, the intrusion of the light generated by the electron detection element 30 into the X-ray detection element 40 and the intrusion of the light generated by the X-ray detection element 40 into the electron detection element 30 are limited, thereby improving the detection accuracy of the “electrons” by the electron detection element 30 and the detection accuracy of the X-rays by the X-ray detection element 40.

### Further Improvements

As described above, the inspection device 100 according to the present embodiment includes the electron detection element 30 for detecting the “electrons” emitted from the sample 20 and the X-ray detection element 40 for detecting the X-rays emitted from the sample 20. Here, the X-ray detection element 40 has an advantage that, for example, the information from the bottom portion of the deep hole can be accurately detected. Meanwhile, the electron detection element 30 has an advantage that a surface shape (information from a surface) of the deep hole can be accurately detected.

Therefore, according to a combination of the advantage of the X-ray detection element 40 and the advantage of the electron detection element 30, it is considered that, for example, the etching defect of the deep hole having a high aspect ratio and a surface shape defect (defect of an opening diameter) of the deep hole can be inspected with high accuracy based on the information of the bottom portion of the deep hole and the information related to the surface shape. That is, the inspection device 100 according to the present embodiment includes the electron detection element 30 and the X-ray detection element 40 having different advantages. It is considered that the performance of the inspection device 100 can be further improved by combining the respective advantages. The improvement will be described below.

### Functional Block Configuration of Control Unit

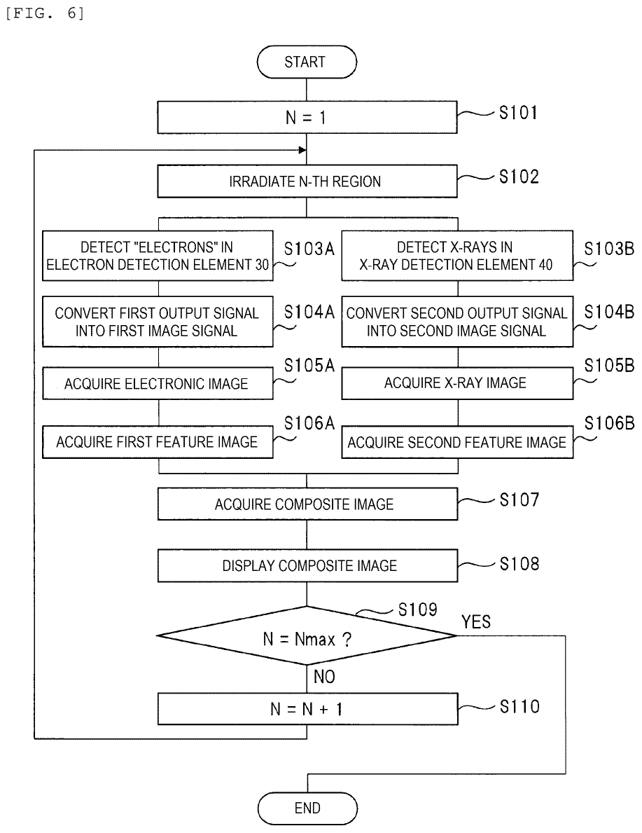

FIG. 5 is a diagram showing a functional block configuration of the control unit 60.

In FIG. 5, the control unit 60 includes an input unit 201, a first image signal conversion unit 202, a second image signal conversion unit 203, an electronic image acquisition unit 204, an X-ray image acquisition unit 205, a first feature image acquisition unit 206, a second feature image acquisition unit 207, a composite image acquisition unit 208, an output unit 209, and a data storage unit 210.

The input unit 201 is implemented to receive a first output signal output from the electron detection element 30 and a second output signal output from the X-ray detection element 40. For example, if the electron detection element 30 includes a first scintillator and the X-ray detection element 40 includes a second scintillator, the first output signal output from the electron detection element 30 is a signal based on the light obtained by converting the “electrons” by the first scintillator. The second output signal output from the X-ray detection element 40 is a signal based on light obtained by converting the X-rays by the second scintillator. At this time, a first output amount output from the electron detection element 30 is a signal amount based on a light amount obtained by converting the “electrons” by the first scintillator. A second output amount output from the X-ray detection element 40 is a signal amount based on the light amount obtained by converting the X-rays by the second scintillator.

The first image signal conversion unit 202 has a function of converting the first output signal input to the input unit 201 into a first image signal. Meanwhile, the second image signal conversion unit 203 has a function of converting the second output signal input to the input unit 201 into a second image signal.

Next, the electronic image acquisition unit 204 is implemented to generate an electronic image based on the first image signal converted by the first image signal conversion unit 202. The electronic image acquired by the electronic image acquisition unit 204 is stored in, for example, the data storage unit 210.

The X-ray image acquisition unit 205 is implemented to generate an X-ray image based on the second image signal converted by the second image signal conversion unit 203. The X-ray image acquired by the X-ray image acquisition unit 205 is stored in, for example, the data storage unit 210. Gradation of a pixel of the X-ray image is based on the light amount obtained by converting the X-rays by the scintillator, and the light amount may be a sum of the light amounts within a certain period of time, or may be a sum of units, with each unit being the light amount equal to or above a reference (or equal to or smaller than the light amount reaching the reference) within a certain period of time.

The first feature image acquisition unit 206 is implemented to read the electronic image generated by the electronic image acquisition unit 204 from the data storage unit 210, and then acquire a first feature image by extracting a feature from the electronic image. The first feature image is stored in the data storage unit 210.

The second feature image acquisition unit 207 is implemented to read the X-ray image generated by the X-ray image acquisition unit 205 from the data storage unit 210, and then acquire a second feature image by extracting a feature from the X-ray image. The second feature image is stored in the data storage unit 210.

Next, the composite image acquisition unit 208 is implemented to acquire, based on the first feature image acquired by the first feature image acquisition unit 206 and the second feature image acquired by the second feature image acquisition unit 207, a composite image in which the feature included in the first feature image and the feature included in the second feature image are combined. The composite image is stored in, for example, the data storage unit 210.

The output unit 209 is implemented to output the composite image acquired by the composite image acquisition unit 208, for example, to the display unit 80. Accordingly, the composite image is displayed on the display unit 80. The control unit 60 is implemented as described above.

### Operation of Inspection Device

Next, an operation of the inspection device 100 corresponding to further improvements will be described.

FIG. 6 is a flowchart showing the operation of the inspection device 100.

In FIG. 6, first, a variable N representing an N-th region of the sample 20 is set to “N=1” (S101). Then, the primary electrons (primary electron beam) emitted from the electron source 10 are applied to the first region of the sample 20 (S102). Accordingly, the “electrons” and the X-rays are emitted from the first region of the sample 20. The emitted “electrons” are detected in the electron detection element 30 (S103A). Meanwhile, the emitted X-rays are transmitted through the electron detection element 30 and are detected by the X-ray detection element 40 (S103B). For example, the detection by the electron detection element 30 for the “electrons” which are emitted from the first region of the sample 20 and the detection by the X-ray detection element 40 for the X-rays which are emitted from the first region of the sample 20 are performed simultaneously.

Next, when the “electrons” are detected by the electron detection element 30, the first output signal corresponding to the detection of the “electrons” is output from the electron detection element 30. Further, the first output signal output from the electron detection element 30 is input to the input unit 201, and then converted into the first image signal in the first image signal conversion unit 202 (S104A).

Meanwhile, when the X-rays are detected by the X-ray detection element 40, the second output signal corresponding to detection of X-rays is output from the X-ray detection element 40. The second output signal output from the X-ray detection element 40 is input to the input unit 201 and then converted into the second image signal in the second image signal conversion unit 203 (S104B).

Subsequently, the electronic image acquisition unit 204 acquires the electronic image based on the first image signal converted by the first image signal conversion unit 202 (S105A). Meanwhile, the X-ray image acquisition unit 205 acquires the X-ray image based on the second image signal converted by the second image signal conversion unit 203 (S105B). The acquired electronic image and X-ray image are stored in the data storage unit 210.

Thereafter, the first feature image acquisition unit 206 extracts a feature from the electronic image acquired by the electronic image acquisition unit 204 to acquire the first feature image (S106A). Meanwhile, the second feature image acquisition unit 207 extracts a feature from the X-ray image acquired by the X-ray image acquisition unit 205 to acquire the second feature image (S106B). The acquired first feature image and second feature image are stored in the data storage unit 210.

Then, the composite image acquisition unit 208 acquires, based on the first feature image acquired by the first feature image acquisition unit 206 and the second feature image acquired by the second feature image acquisition unit 207, the composite image in which the feature included in the first feature image and the feature included in the second feature image are combined (S107). At this time, the acquired composite image is stored in the data storage unit 210.

Next, the output unit 209 outputs the composite image acquired by the composite image acquisition unit 208, for example, to the display unit 80 (S108). Accordingly, the composite image is displayed on the display unit 80.

Thereafter, the control unit 60 determines whether the N-th region of the sample 20 is a final scanning region (Nmax) of the inspection (S109). As a result, when the N-th region of the sample 20 is not the final scanning region (Nmax) of the inspection, “N=N+1” is set, the processing returns to S102, and the same operation is repeated in an (N+1)-th region of the sample 20. On the other hand, when the N-th region of the sample 20 is the final scanning region (Nmax) of the inspection, the operation of the inspection device 100 ends.

The inspection device 100 operates as described above.

### Feature of Further Improvements

A feature of further improvement is that the composite image is generated by combining the feature included in the electronic image based on the output from the electron detection element 30 and the feature included in the X-ray image based on the output from the X-ray detection element 40. Further, the inspection of the sample 20 is performed based on the generated composite image, so that the inspection with higher accuracy can be performed. That is, according to further improvement, the advantage of the electron detection element 30 and the advantage of the X-ray detection element 40 can be effectively used in combination, so that inspection performance in the inspection device 100 can be improved.

### SPECIFIC EXAMPLE

A specific example will be described below.

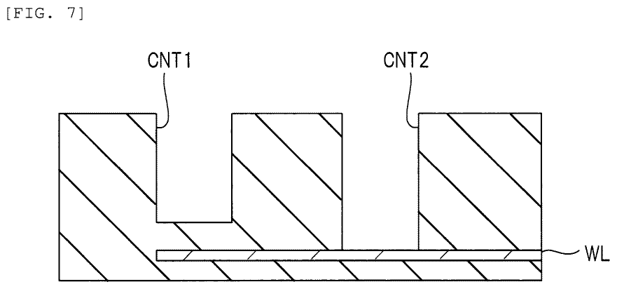

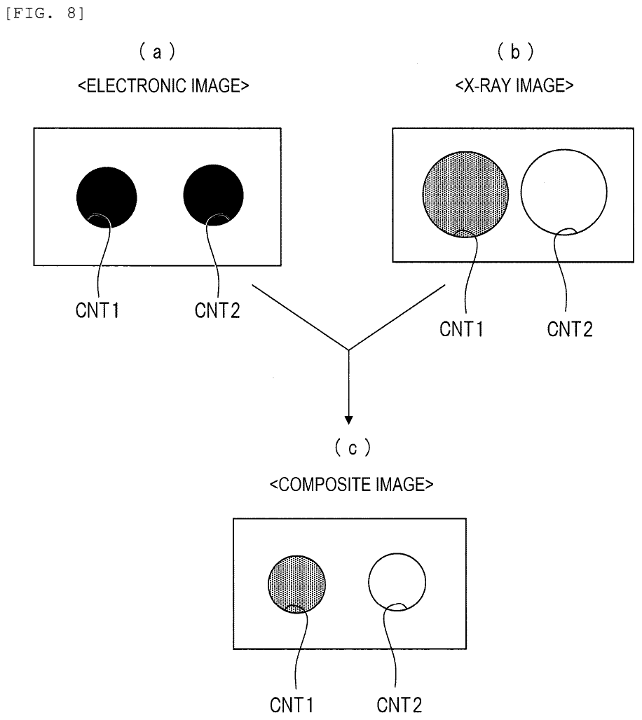

FIG. 7 is a schematic view showing the deep hole sample. FIG. 7 shows a deep hole CNT1 and a deep hole CNT2. The deep hole CNT2 is etched to reach a wiring WL, and indicates a normal deep hole. On the other hand, the deep hole CNT1 does not reach the wiring WL and indicates a deep hole with an etching defect. Hereinafter, it is considered that the deep hole sample shown in FIG. 7 is inspected by the inspection device 100 in the present embodiment.

(a) of FIG. 8 is a diagram schematically showing an electronic image generated based on the output from the electron detection element 30, and (b) of FIG. 8 is a diagram schematically showing an X-ray image generated based on the output from the X-ray detection element 40. In addition, (c) of FIG. 8 is a diagram showing a composite image obtained by combining the feature of the electronic image and the feature of the X-ray image.

In (a) of FIG. 8, since it is difficult to obtain information from the bottom portion of the deep hole having a high aspect ratio using the electron detection element 30, there is no difference in contrast between the deep hole CNT1 and the deep hole CNT2 contained in the electronic image. Therefore, the deep hole CNT1 with the etching defect and the normal deep hole CNT2 shown in FIG. 7 cannot be distinguished by the single electronic image.

However, the advantage of the electronic image based on the output of the electron detection element 30 is that the surface shape of the sample is accurately reflected. Therefore, an opening diameter of the deep hole CNT1 and an opening diameter of the deep hole CNT2 in (a) of FIG. 8 are accurate. That is, the feature (advantage) of the electronic image shown in (a) of FIG. 8 is that the opening diameter of the deep hole CNT1 and the opening diameter of the deep hole CNT2 are accurate.

Next, as shown in (b) of FIG. 8, since it is possible to obtain information from the bottom portion of the deep hole having a high aspect ratio using the X-ray detection element 40, it is understood that there is a difference in contrast between the deep hole CNT1 and the deep hole CNT2 contained in the X-ray image. That is, in the X-ray image shown in (b) of FIG. 8, the deep hole CNT1 with the etching defect and the normal deep hole CNT2 shown in FIG. 7 can be distinguished based on a contrast difference. As described above, the feature (advantage) of the X-ray image shown in (b) of FIG. 8 is that the contrast difference occurs between the deep hole CNT1 with the etching defect and the normal deep hole CNT2.

However, it is difficult for the X-ray image based on the output of the X-ray detection element 40 to accurately reflect the surface shape of the sample than the electronic image based on the output of the electron detection element 30. That is, in the X-ray image shown in (b) of FIG. 8, the opening diameter of the deep hole CNT1 and the opening diameter of the deep hole CNT2 are inaccurate, and are larger than the electronic image shown in (a) of FIG. 8. That is, in the X-ray image shown in (b) of FIG. 8, the opening diameter of the deep hole CNT1 and the opening diameter of the deep hole CNT2 are inaccurate, and are more blurred than the electronic image shown in (a) of FIG. 8.

As described above, the advantage of the electronic image shown in (a) of FIG. 8 is that the opening diameter of the deep hole CNT1 and the opening diameter of the deep hole CNT2 are accurate, and the advantage of the X-ray image shown in (b) of FIG. 8 is that the deep hole CNT1 with the etching defect and the normal deep hole CNT2 can be distinguished based on the contrast difference. In the inspection device 100, the advantage of the electronic image shown in (a) of FIG. 8 and the advantage of the X-ray image shown in (b) of FIG. 8 are combined to generate a composite image.

As shown in (c) of FIG. 8, it is understood that the composite image incorporates the advantage of the electronic image shown in (a) of FIG. 8 (contours of the deep hole CNT1 and the deep hole CNT2) and the advantage of the X-ray image shown in (b) of FIG. 8 (contrast difference between the deep hole CNT1 and the deep hole CNT2).

Therefore, according to the inspection using the composite image shown in (c) of FIG. 8, the deep hole CNT1 with the etching defect can be identified based on the contrast difference between the deep hole CNT1 and the deep hole CNT2. Further, presence or absence of an abnormality in the opening diameter can be inspected based on the contours of the deep hole CNT1 and the deep hole CNT2. As described above, according to the inspection device 100 having the “further improvement”, the inspection accuracy can be improved. In other words, the performance of the inspection device 100 can be improved.

Although the invention made by the present inventors has been specifically described based on the embodiment, the invention is not limited to the embodiment, and it is needless to say that various modifications can be made without departing from the gist of the invention.

### REFERENCE SIGNS LIST

10: electron source
11: converging lens
12: deflector
13: objective lens
14: sample stage
20: sample
30: electron detection element
40: X-ray detection element
50: inspection element
60: control unit
70: crosstalk limit unit
80: display unit
100: inspection device
201: input unit
202: first image signal conversion unit
203: second image signal conversion unit
204: electronic image acquisition unit
205: X-ray image acquisition unit
206: first feature image acquisition unit
207: second feature image acquisition unit
208: composite image acquisition unit
209: output unit
210: data storage unit
CNT1: deep hole
CNT2: deep hole
WL: wiring

1. An inspection device comprising:
an electron source configured to generate primary electrons to be incident on a sample;
an electron detection element located between a sample stage on which the sample is allowed to be provided and the electron source; and
an X-ray detection element located between the electron detection element and the electron source, wherein
the electron detection element includes a first scintillator that detects electrons emitted from the sample, and
the X-ray detection element is configured to detect an X-ray emitted from the sample, that is, the X-ray transmitted through the electron detection element.

2. The inspection device according to claim 1, wherein
the X-ray detection element includes a second scintillator.

3. The inspection device according to claim 1, wherein
the electron detection element is an annular element, and
the X-ray detection element is an annular element.

4. The inspection device according to claim 1, wherein
when viewed from a plane perpendicular to an incident direction of the primary electrons,
a planar shape of the electron detection element is a concentric circular shape, and
a planar shape of the X-ray detection element is a concentric circular shape.

5. The inspection device according to claim 1, wherein
detection of the electrons in the electron detection element and detection of the X-ray in the X-ray detection element are performed simultaneously.

6. The inspection device according to claim 1, further comprising:
a first image signal conversion unit configured to convert an output from the electron detection element into a first image signal;
an electronic image acquisition unit configured to acquire an electronic image based on the first image signal;
a second image signal conversion unit configured to convert an output from the X-ray detection element into a second image signal; and
an X-ray image acquisition unit configured to acquire an X-ray image based on the second image signal.

7. The inspection device according to claim 6, wherein
the X-ray detection element includes a second scintillator, and
an output amount from the X-ray detection element is a signal amount based on a light amount obtained by converting the X-ray by the second scintillator.

8. The inspection device according to claim 7, wherein
gradation of a pixel in the X-ray image is an amount based on a sum of light amounts obtained by conversion by the second scintillator of the X-ray detection element in a certain period of time.

9. The inspection device according to claim 6, wherein
when the primary electrons are emitted onto a first region of the sample,
the electron detection element detects an electron emitted from the first region,
the X-ray detection element detects an X-ray emitted from the first region,
the electronic image acquisition unit acquires a first electronic image corresponding to the first region, and
the X-ray image acquisition unit acquires a first X-ray image corresponding to the first region.

10. The inspection device according to claim 9, further comprising:
a first feature image acquisition unit configured to acquire a first feature image by extracting a feature of the first electronic image;
a second feature image acquisition unit configured to acquire a second feature image by extracting a feature of the first X-ray image; and
a composite image acquisition unit configured to acquire a composite image based on the first feature image and the second feature image.

11. The inspection device according to claim 1, wherein
incidence of the electrons emitted from the sample on the X-ray detection element is limited by the electron detection element provided between the sample stage and the X-ray detection element.

12. The inspection device according to claim 2, wherein
a crosstalk limit unit is provided between the electron detection element and the X-ray detection element to limit crosstalk between light generated from the first scintillator included in the electron detection element and light generated from the second scintillator included in the X-ray detection element.

13. The inspection device according to claim 12, wherein
the crosstalk limit unit includes a shielding film that shields the light generated from the first scintillator included in the electron detection element and the light generated from the second scintillator included in the X-ray detection element.

14. The inspection device according to claim 12, wherein
the crosstalk limit unit includes a film having a refractive index different from a refractive index of a material constituting the electron detection element and a refractive index of a material constituting the X-ray detection element, or a space region having a refractive index different from the refractive index of the material constituting the electron detection element and the refractive index of the material constituting the X-ray detection element.

15. An inspection element that is allowed to be incorporated into an inspection device that causes primary electrons generated by an electron source to be incident on a sample provided on a sample stage and detects an electron and an X-ray emitted from the sample, the inspection element comprising:
an electron detection element that is allowed to be provided between the sample stage and the electron source; and
an X-ray detection element that is allowed to be provided between the electron detection element and the electron source, wherein
the electron detection element includes a first scintillator that detects the electron emitted from the sample, and
the X-ray detection element is configured to detect the X-ray emitted from the sample, that is, the X-ray transmitted through the electron detection element.

16. The inspection element according to claim 15, wherein
the X-ray detection element includes a second scintillator.

17. The inspection element according to claim 15, wherein
the electron detection element is an annular element, and
the X-ray detection element is an annular element.

18. The inspection element according to claim 15, wherein
when viewed from a plane perpendicular to an incident direction of the primary electrons,
a planar shape of the electron detection element is a concentric circular shape, and
a planar shape of the X-ray detection element is a concentric circular shape.

19. The inspection element according to claim 15, wherein
detection of the electrons in the electron detection element and detection of the X-ray in the X-ray detection element are performed simultaneously.

20. The inspection element according to claim 16, wherein
an output amount from the X-ray detection element is a signal amount based on a light amount obtained by converting the X-ray by the second scintillator.

21. The inspection element according to claim 15, wherein
incidence of the electrons emitted from the sample on the X-ray detection element is limited by the electron detection element provided between the sample stage and the X-ray detection element.

22. The inspection element according to claim 16, wherein
a crosstalk limit unit is provided between the electron detection element and the X-ray detection element to limit crosstalk between light generated from the first scintillator included in the electron detection element and light generated from the second scintillator included in the X-ray detection element.

23. An inspection method comprising:
a step of causing primary electrons generated by an electron source to be incident on a sample; and
a step of detecting an electron emitted from the sample by an electron detection element which is located between a sample stage on which the sample is provided and the electron source and which includes a scintillator, and detecting an X-ray emitted from the sample, that is, the X-ray transmitted through the electron detection element by an X-ray detection element located between the electron detection element and the electron source.

24. The inspection method according to claim 23, wherein
the electron detection element is an annular element, and
the X-ray detection element is an annular element.
